(19) United States
(12) Patent Application Publication
(10) Pub. No.: US 2008/0296056 A1
(43) Pub. Date: Dec. 4, 2008

(54) Printed circuit board, production method therefor, electronic-component carrier board using printed circuit board, and production method therefor

(75) Inventors: Tohru Kinoshita, Kanagawa-Ken (JP); Toshinobu Kanai, Kanagawa-Ken (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Victor Company of Japan, Ltd., Yokohama-shi (JP)

(21) Appl. No.: 12/079,055

(22) Filed: Mar. 24, 2008

(30) Foreign Application Priority Data
May 31, 2007 (JP) JP 2007-145198

(51) Int. Cl. H05K 3/10; H01R 12/06

(52) U.S. Cl. 174/261; 29/846

(57) ABSTRACT

A printed wiring board has a substrate having a first surface and a second surface on both sides of the substrate. A cavity is provided on the first surface. The cavity caves in towards the second surface. Several bumps are formed in the cavity as protruding towards the first surface. An insulation layer is filled in the cavity. The bumps are isolated from one another by the insulation layer. The top of each bump that protrudes towards the first surface and a zone in the cavity and close to the top are exposed in the cavity without being covered by the insulation layer.

### CROSS-REFERENCE TO RELATED APPLICATIONS

This application is based on and claims the benefit of priority from the prior Japanese Patent Application No. 2007-145198 filed on May 31, 2007, the entire contents of which is incorporated herein by reference.

### BACKGROUND OF THE INVENTION

The present invention relates to a printed circuit board, a method of producing the printed circuit board, an electronic-component carrier board using the printed circuit board, and a method of producing the electronic-component carrier board. Especially, this invention relates to a printed circuit board having cavities with electronic components, such as semiconductors, housed therein, a method of producing the printed circuit board, an electronic-component carrier board using the printed circuit board, and a method of producing the electronic-component carrier board.

Electronic equipment, such as a personal computer, employs an electronic-component carrier board, such as a semiconductor package, having cavities with electronic components, such as semiconductors, housed therein.

Such an electronic-component carrier board is, typically, a ceramic substrate or a printed circuit board made of a resin substrate. The printed circuit board has become more popular than the ceramic board, as the electronic-component carrier board. This is because the former is advantageous over the latter in weight lightness, wiring-pattern miniaturization, and productivity.

Electrical connections between a printed circuit board and electronic components, such as semiconductor devices, are achieved by several techniques, such as, wire bonding and flip chip technologies.

Wire bonding, however, poses several problems to recent larger scale integration of semiconductor devices with increased number of terminals that connect a printed circuit board and semiconductor devices. In detail, such terminals are provided on several wiring layers of the printed circuit board, which results in a further multi-layered and a larger structure for the printed circuit board, or the electronic-component carrier board using this printed circuit board.

Moreover, wire bonding is performed for each connection terminal. Time required for wire bonding thus becomes longer as the number of such terminal increases, which results in lower productivity.

The flip chip technology also has difficulty in printing bumps in cavities for connection terminals provided in the cavities of a printed circuit board.

Such bumps can be formed with wire bonding, which, however, results in a further multi-layered and a larger structure for the printed circuit board, or the electronic-component carrier board using this printed circuit board and also lower productivity, according to the same reason as discussed above.

### SUMMARY OF THE INVENTION

A purpose of the present invention is to provide a printed circuit board, a method of producing the printed circuit board, an electronic-component carrier board using the printed circuit board, and a method of producing the electronic-component carrier board, that allow the flip chip technology to mount electronic components, such as semiconductor devices, on the printed circuit board, with no such problems of a further multi-layered and a larger structure for the printed circuit board, or the electronic-component carrier board using this printed circuit board and also lower productivity.

The present invention provides a printed wiring board comprising: a substrate having a first surface and a second surface on both sides of the substrate; a cavity provided on the first surface that caves in towards the second surface; a plurality of bumps formed in the cavity that protrude towards the first surface; an insulation layer filled in the cavity, the bumps being isolated from one another by the insulation layer, a top of each bump that protrudes towards the first surface and a zone in the cavity and close to the top being exposed in the cavity without being covered by the insulation layer.

Moreover, the present invention provides a method of producing a printed wiring board comprising the steps of: forming a plurality of bumps on a substrate surface; forming an insulation layer having a sheet-like reinforcement material and insulating resin on the substrate surface to cover the bumps with the reinforcement material via the insulating resin; removing the reinforcement material from a zone on the substrate surface having the bumps formed in the zone so that the insulating material on the bumps remains; and emitting a laser beam to the insulating material that remains on the bumps to remove the insulating material so that the bumps are exposed on the substrate surface.

Furthermore, the present invention provides an electronic-component carrier board comprising: a substrate having a first surface and a second surface on both sides of the substrate; a cavity provided on the first surface that caves in towards the second surface; a plurality of bumps formed in the cavity that protrude towards the first surface; an insulation layer filled in the cavity, the bumps being isolated from one another by the insulation layer, a top of each bump that protrudes towards the first surface and a zone in the cavity and close to the top being exposed in the cavity without being covered by the insulation layer; and at least one electronic component housed in the cavity and having a plurality of electrodes that are electrically connected to the bumps.

Still, furthermore, the present invention provides a method of producing an electronic-component carrier board comprising the steps of: forming a plurality of bumps on a substrate surface; forming an insulation layer having a sheet-like reinforcement material and insulating resin on the substrate surface to cover the bumps with the reinforcement material via the insulating resin; removing the reinforcement material from a zone on the substrate surface having the bumps formed in the zone so that the insulating material on the bumps remains; emitting a laser beam to the insulating material that remains on the bumps to remove the insulating material so that the bumps are exposed on the substrate surface; housing at least one electronic component having a plurality of electrodes in the cavity; and electrically connecting the electrodes to the bumps.

### BRIEF DESCRIPTION OF DRAWINGS

FIG. 1 is a schematic sectional view illustrating a first step of a method of producing a printed circuit board according to the present invention;

FIG. 2 is a schematic sectional view illustrating a second step of the method of producing the printed circuit board according to the present invention;

FIG. 3 is a schematic sectional view illustrating a third step of the method of producing the printed circuit board according to the present invention;

FIG. 4 is a schematic sectional view illustrating a fourth step of the method of producing the printed circuit board according to the present invention;

FIG. 5 is a schematic sectional view illustrating a fifth step of the method of producing the printed circuit board according to the present invention;

FIG. 6 is a schematic sectional view illustrating a sixth step of the method of producing the printed circuit board according to the present invention;

FIG. 7 is a schematic sectional view illustrating a seventh step of the method of producing the printed circuit board according to the present invention;

FIG. 8 is a schematic sectional view illustrating an eighth step of the method of producing the printed circuit board according to the present invention;

FIG. 9 is a schematic sectional view illustrating a ninth step of the method of producing the (multi-layered) printed circuit board according to the present invention;

FIG. 10 is a schematic sectional view illustrating a tenth step of the method of producing the printed circuit board according to the present invention;

FIG. 11 is a schematic sectional view illustrating an eleventh step of the method of producing the printed circuit board according to the present invention;

FIG. 12 is a schematic sectional view illustrating a twelfth step of the method of producing the (multi-layered) printed circuit board according to the present invention;

FIG. 13 is a schematic sectional view illustrating a thirteenth step of the method of producing the printed circuit board according to the present invention;

FIG. 14 is a schematic sectional view illustrating a fourteenth step of the method of producing the printed circuit board (electronic-component carrier board) according to the present invention;

FIG. 15 is a schematic sectional view illustrating a fifteenth step of the method of producing the printed circuit board (electronic-component carrier board) according to the present invention; and

FIG. 16 is a schematic sectional view illustrating a modification to the methods and the printed circuit board (electronic-component carrier board) shown in the above figures, according to the present invention.

### DETAILED DESCRIPTION OF PREFERRED EMBODIMENTS

Embodiments of a printed circuit board, a method of producing the printed circuit board, an electronic-component carrier board using the printed circuit board, and a method of producing the electronic-component carrier board will be disclosed with reference to the attached drawings.

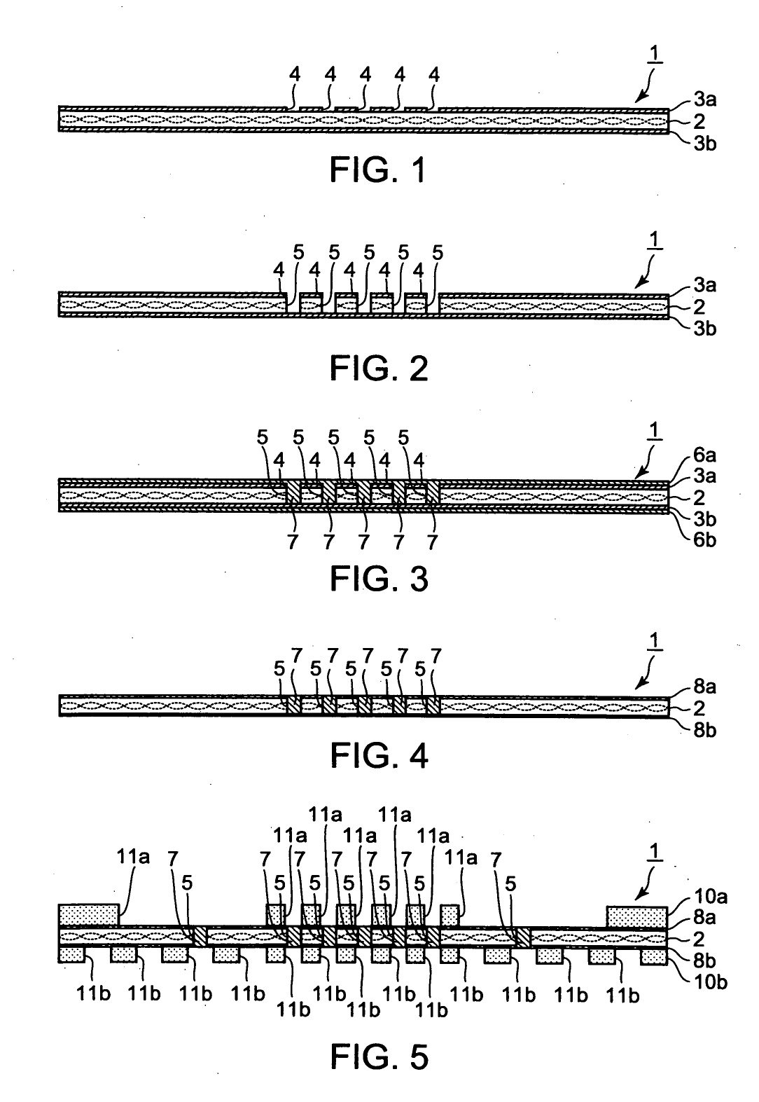

Disclosed first with reference to FIGS. 1 to 13 are embodiments of a printed circuit board having cavities with electronic components, such as semiconductor devices, housed therein and a method of producing the printed circuit board.

[First Step in FIG. 1]

Prepared first is a board (or substrate) 1 composed mainly of a core material 2 and copper foils 3a and 3b on both sides. The copper foil 3a is then partially etched to have openings 4 so that the core material 2 is exposed therethrough. The core material 2 is made of a sheet-like reinforcement material (or stiffener), such as glass cloth, impregnated with insulating resin, such as epoxy resin and hardened. The reinforcement material is illustrated with dash lines in FIG. 1.

In this embodiment: the core material 2 has a thickness of 0.1 mm; the copper foils 3a and 3b have a thickness of 12 μm; and the openings 4 have an entrance diameter of 80 μm.

[Second Step in FIG. 2]

The core material 2 is partially removed by a removal process, for example, laser drilling, through the openings 4, to have holes 5 so that the copper foil 3b is exposed therethrough. The holes 5 have a diameter of 80 μm in this embodiment.

[Third Step in FIG. 3]Conductive layers 6a and 6b are formed on the copper foils 3a and 3b, respectively. The holes 5 are filled with the conductive layer 6a. The conductive layers 6a and 6b may be formed by electroless copper plating and then copper electroplating to the board (or substrate) 1 that has undergone the second step.

The holes 5 filled with the conductive layer 6a will become vias 7 (having 80 μm in diameter in this embodiment) for use in electrical connection between a first wiring layer 15 and a second wiring layer 16, which will be disclosed later.

In this embodiment, the conductive layers 6a and 6b have a thickness of 30 μm on the copper foils 3a and 3b, respectively.

[Fourth Step in FIG. 4]

The conductive layers 6a and 6b and then the copper foils 3a and 3b are etched away to have conductive thin films 8a and 8b on both sides of the core material 1, for use in electroplating in the following sixth step. In this embodiment, the films 8a and 8b have a thickness of about 3 μm.

[Fifth Step in FIG. 5]

A resist pattern 10a (for use in plating) is formed on the conductive thin film 8a by photolithography, as having openings 11a through which the film 8a is exposed. Another resist pattern 10b (for use in plating) is formed on the conductive thin film 8b by photolithography, as having openings 11b through which the film 8b is exposed.

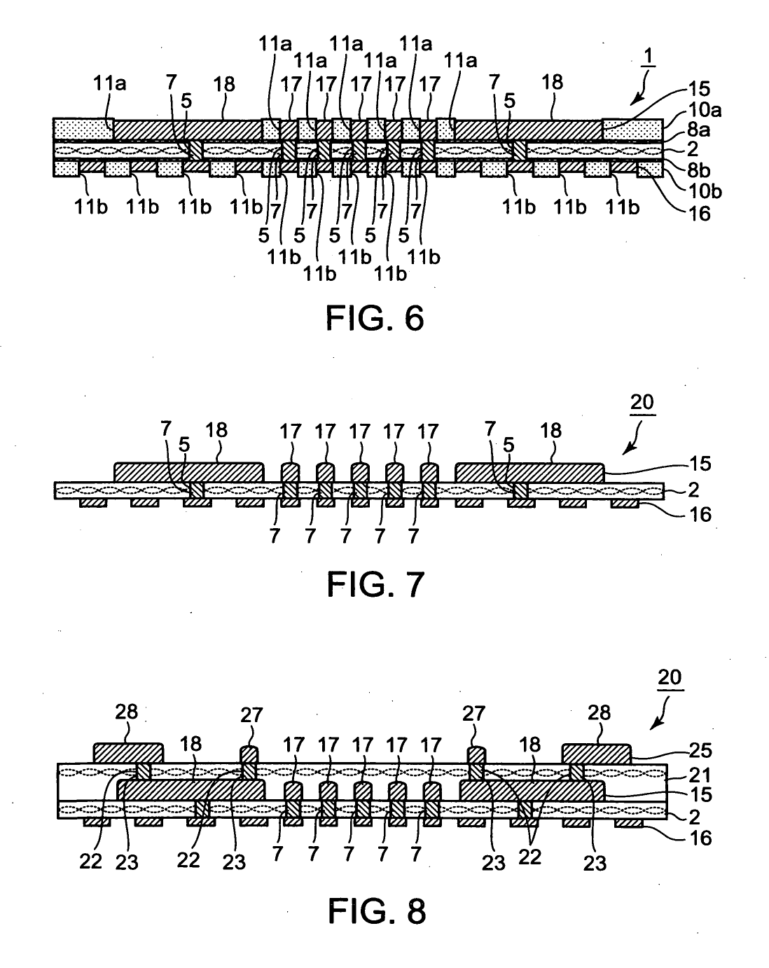

In this embodiment, the resist patterns 10a and 10b have thicknesses of 80 μm and 50 μm, respectively.

[Sixth Step in FIG. 6]

Electroplating, for example, copper electroplating, is performed to the zone of the conductive thin film 8a (as a conductive layer for electroplating) where openings 11a are provided, to form the first wiring layer 15 composed of a wiring pattern 18 and first pillar-like conductors 17. In the same way, electroplating, for example, copper electroplating, is performed to the zone of the conductive thin film 8b (as a conductive layer for electroplating) where openings 11b are provided, to form the second wiring layer 16. The first and second wiring layers 15 and 16 can be simultaneously formed with one electroplating process.

In this embodiment, electroplating is controlled so that the first conductors 17 (of the first wiring layer 15) have a cylindrical shape with a diameter of 110 μm and a height of 60 μm and the second wiring layer 16 has a thickness of 20 μm.

[Seventh Step in FIG. 7]

The resist patterns 10a and 10b used for the electroplating are removed to expose the conductive thin films 8a and 8b, respectively. The exposed films 8a and 8b are further removed to obtain a double-sided wiring board 20 in which the first and second wiring layers 15 and 16 are electrically connected through the vias 7.

When the conductive thin films 8a and 8b are removed, the first conductors 17, the wiring pattern 18, and the second wiring layer 16 are also removed for their surface zones each including the surface and a zone near to the surface. The first conductors 17 and the wiring pattern 18 then have round edges, as shown in FIG. 7.

[Eighth Step in FIG. 8]

A first insulation layer 21 is formed on the core material 2 to cover the first wiring layer 15, by a known process, such as, vacuum thermal press. The insulation layer 21 is made of a sheet-like reinforcement material, such as glass cloth, impregnated with insulating resin, such as epoxy resin and hardened. The reinforcement material is illustrated with dash lines in FIG. 8, in the same way as in FIG. 1.

In this embodiment, the first insulation layer 21 has a thickness of 0.2 mm on the first wiring layer 15.

The first insulation layer 21 is partially removed by a removal process, for example, laser drilling, to have holes 22 so that the wiring pattern 18 is exposed therethrough.

A conductive layer (not shown) is formed on the first insulation layer 21 so that the holes 22 are filled with the conductive layer. The conductive layer is then removed from the insulation layer 21 except for those filled in the holes 22, thus forming vias 23.

Several processes, such as the fifth to seventh steps, are applied to the surface of the first insulation layer 21, to form a third wiring layer 25 with a wiring pattern 28 and second pillar-like conductors 27.

The above processes achieve electrical connections between the first and third wiring layers 15 and 25 through the vias 23.

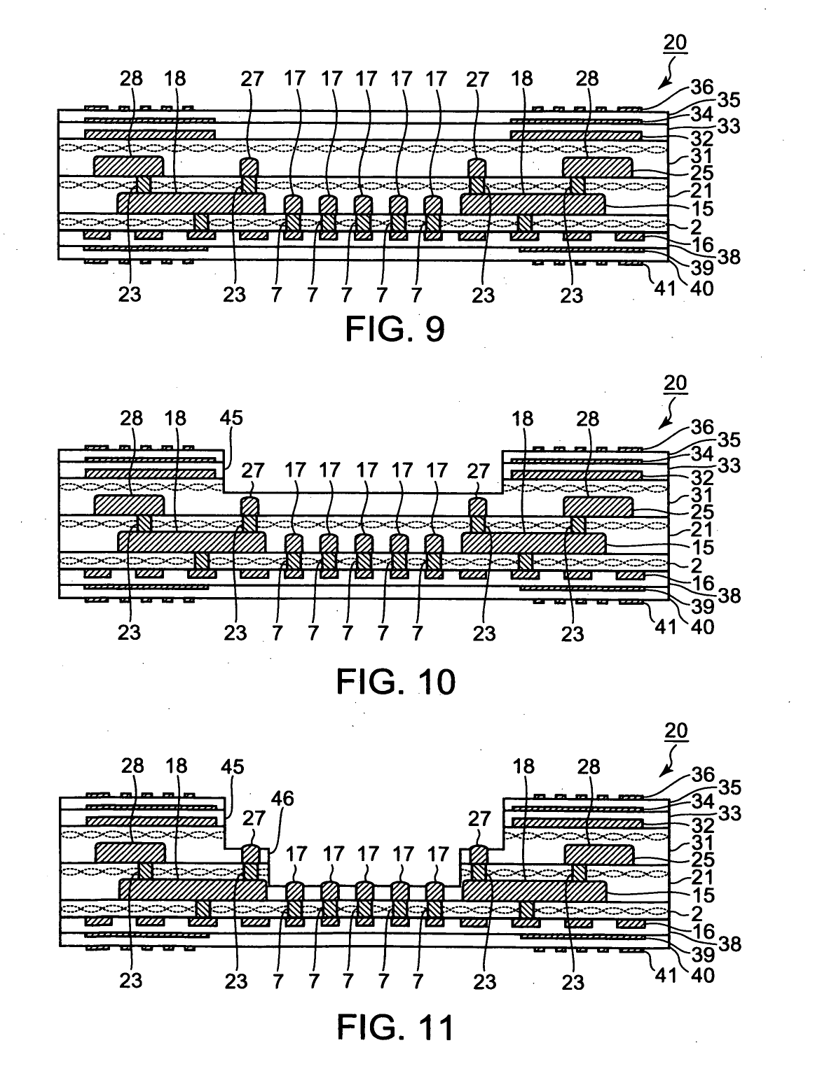

In this embodiment, the vias 23 have a diameter of 80 μm and the second pillar-like conductors 27 have a diameter of 110 μm and a height of 60 μm in a cylindrical shape.

[Ninth Step in FIG. 9]

A second insulation layer 31, a fourth wiring layer 32, a third insulation layer 33, a fifth wiring layer 34, a fourth insulation layer 35, and a sixth wiring layer 36 are formed in order by known processes on the double-sided wiring board 20 at the first insulation layer 21's side (the upper side in FIG. 9), that has undergone the eighth step.

The second insulation layer 31 is made of a sheet-like reinforcement material, such as glass cloth, impregnated with insulating resin, such as epoxy resin and hardened. The reinforcement material is illustrated with dash lines in FIG. 9, in the same way as in FIG. 1.

In this embodiment, the second insulation layer 31 has a thickness of 0.2 mm on the third wiring layer 25.

Also formed in order on the double-sided wiring board 20 but at the core material 2's side (the lower side in FIG. 9), that has undergone the eighth step, by known processes are a fifth insulation layer 38, a seventh wiring layer 39, a sixth insulation layer 40, and an eighth wiring layer 41.

Electrical connections are achieved by several vias and through holes among the first, second, third, fourth, fifth, sixth, seventh, and eighth conductive layers 15, 16, 25, 32, 34, 36, 39, and 41.

In this embodiment, the third, fourth, fifth, and sixth insulation layers 33, 35, 38, and 40 are made of hardened insulating resin, such as epoxy resin.

Moreover, In this embodiment, roll coating is employed to give a thickness of 70 μm to each of the following insulation layers: the third insulation layer 33 on the fourth wiring layer 32; the fourth insulation layer 35 on the fifth wiring layer 34; the fifth insulation layer 38 on the second wiring layer 16 (the lower side in FIG. 9); and the sixth insulation layer 40 on the seventh wiring layer 39 (the lower side in FIG. 9).

[Tenth Step in FIG. 10]

The fourth insulation layer 35, the third insulation layer 33, and the second insulation layer 31 are partially removed by a mechanical processing, such as drilling, from the zone in which the first and second conductors 17 and 27 have been formed, to have a first counterbore 45.

In detail, the fourth insulation layer 35 and the third insulation layer 33 are completely removed from the zone in which the first and second conductors 17 and 27 have been formed. The second insulation layer 31 made of the sheet-like reinforcement material and impregnated with the insulating resin is removed from this zone as follows: The reinforcement material is completely removed. However, the insulating resin is removed partially so as not to expose the second conductors 27.

In the case of drilling, adequate depth adjustments at a drilling machine (not shown) provides a required depth to the first counterbore 45.

[Eleventh Step in FIG. 11]

The first insulation layer 21 is partially removed by a mechanical processing, such as drilling, from the zone in which the first conductors 17 have been formed, to have a second counterbore 46. No processing is applied to the zone in which the second conductors 27 have been formed.

In detail, the first insulation layer 21 made of the sheet-like reinforcement material and impregnated with the insulating resin is removed from the zone of the first conductors 17 as follows: The reinforcement material is completely removed. However, the insulating resin is removed partially so as not to expose the first conductors 17.

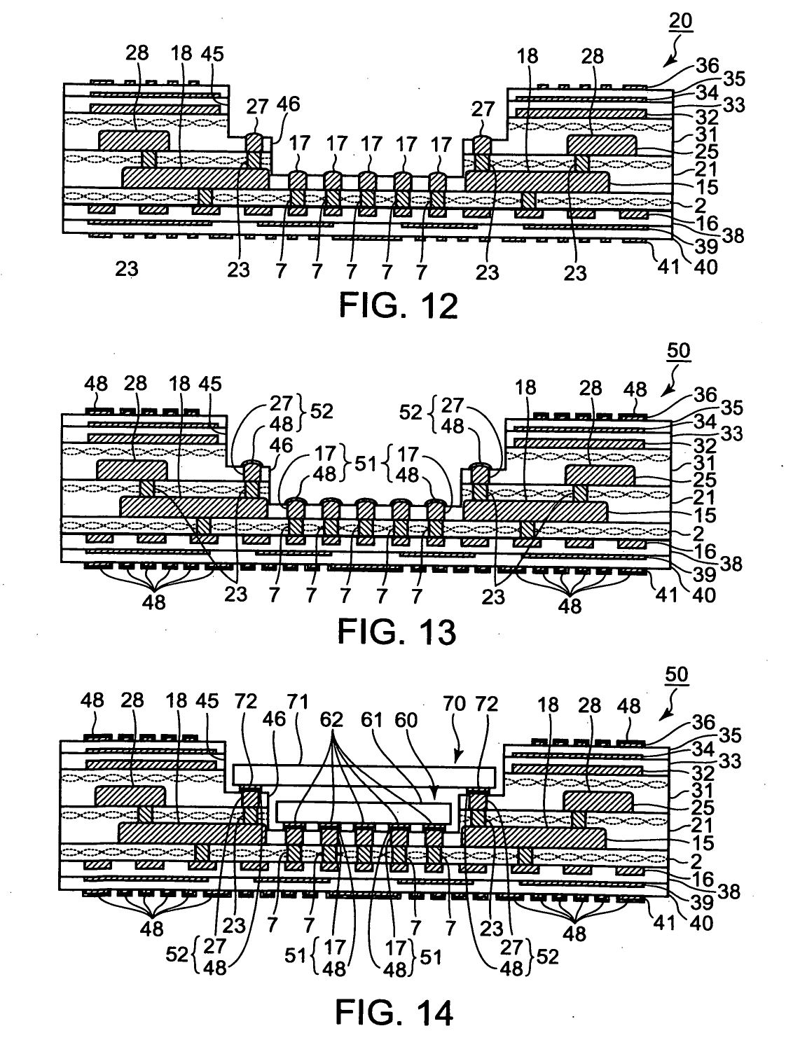

In the case of drilling, adequate depth adjustments at a drilling machine (not shown) provide a required depth to the second counterbore 46.

[Twelfth Step in FIG. 12]

The first and second insulation layers 21 and 31 are partially removed from the zone of the double-sided wiring board 20 in which the first and second counterbores 45 and 46 have been formed, by laser processing to scan a laser over the zone. The laser processing exposes the top of each of the first and second insulation layers 21 and 31, and also the neighboring areas.

In this embodiment, the laser used in the laser processing is a short-pulse CO₂ laser having a peak wavelength of 9.1 μm to 10.6 μm. It may, however, be an excimer laser or a YAG laser having a peak wavelength of 265 nm to 533 nm.

The sheet-like reinforcement material, such as glass cloth, exhibits lower laser processability than the insulating resin. This is the reason for the tenth to twelfth steps in which the zone including the sheet-like reinforcement material is removed by the mechanical processing, such as drilling, and then the zone including only the insulating resin with no sheet-like reinforcement material is removed by the laser processing. These mechanical and laser processing expose the first and second conductors 17 and 27 in a precise manner.

[Thirteenth Step in FIG. 13]

The residual materials at the laser processing in the twelfth step are removed by a removal process, such as, oxidation processing with a potassium permanganate solution, plasma processing, and blast processing.

Electroless copper plating is applied to the double-sided wiring board 20 (FIG. 12) that has undergone the removal process, to form gold-plated layers 48 on the exposed surfaces of the first and second conductors 17 and 27, and the sixth and eighth wiring layers 36 and 41.

The first to thirteenth steps provide a printed circuit board 50 having eight wiring layers of the first to eighth wiring layers 15, 16, 25, 32, 34, 36, 39 and 41.

In the printed circuit board 50, the first and second counterbore 45 and 46 are used as cavities in which electronic components, such as semiconductor devices 60 and 70 (which will be described later), are installed. Also in the printed circuit board 50, the first and second conductors 17 and 27 covered with the gold-plated layers 48 are used as first and second bumps 51 and 52 for use in electrical connections between the electronic components and the printed circuit board 50.

The first bumps 51 are isolated from one another by the first insulation layer 21. The second bumps 52 are isolated from one another by the second insulation layer 31. The first and second insulation layers 21 and 31 function as underfill when electronic components, such as semiconductor devices 60 and 70, are mounted on the printed circuit board 50 by flip chip mounting.

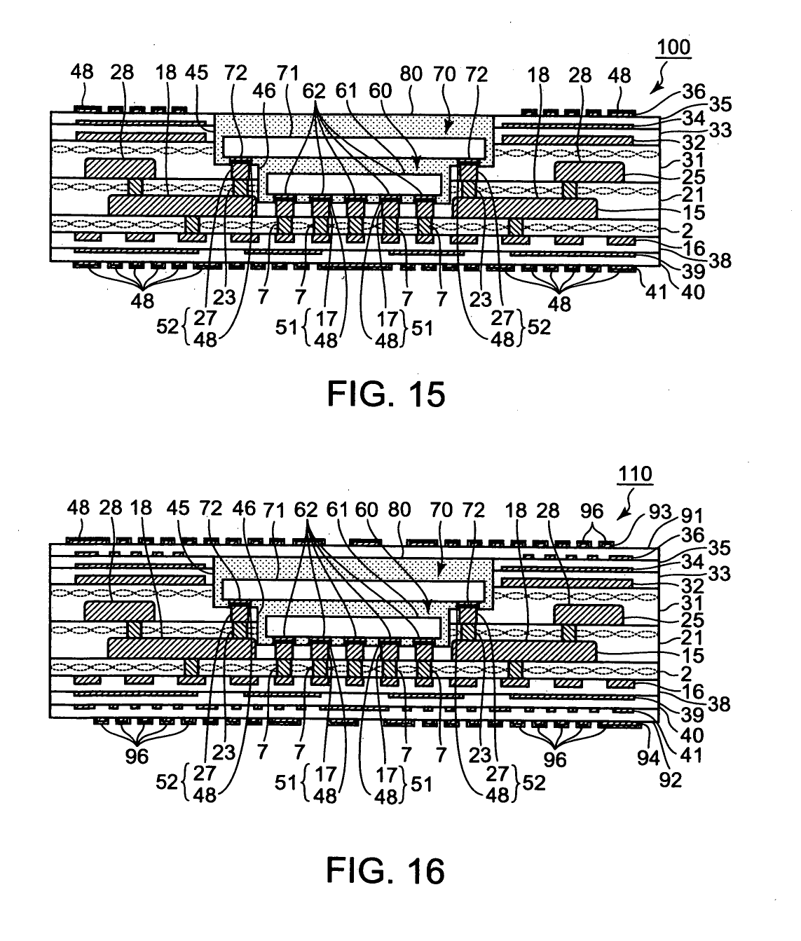

Disclosed next with reference to FIGS. 14 and 15 are an electronic-component carrier board on which electronic components, such as semiconductor devices 60 and 70, are mounted and a method of producing such an electronic-component carrier board.

[Fourteenth Step in FIG. 14]

Prepared first as an electronic component is the semiconductor device 60 with several electrodes 62 formed on one surface of a semiconductor substrate 61. Positioning is made so that the electrodes 62 and the first bumps 51 face each other. The semiconductor device 60 is then mounted on the printed circuit board 50 by flip chip mounting.

In this embodiment, thermal compression boding with ultrasonic waves is employed to simultaneously bond the electrodes 62 and the first bumps 51 to each other.

The flip chip mounting provides electrical connections between the semiconductor device 60 and the printed circuit board 50 via the electrodes 62 and the first bumps 51.

Prepared next as an electronic component is the semiconductor device 70 with several electrodes 72 formed on one surface of a semiconductor substrate 71. Positioning is made so that the electrodes 72 and the second bumps 52 face each other. The semiconductor device 70 is then mounted on the printed circuit board 50 by flip chip mounting.

In this embodiment, thermal compression boding with ultrasonic waves is employed to simultaneously bond the electrodes 72 and the second bumps 52 with each other.

The flip chip mounting provides electrical connections between the semiconductor device 70 and the printed circuit board 50 via the electrodes 72 and the second bumps 52.

[Fifteen Step in FIG. 15]

The cavities, or the first and second counterbores 45 and 46, are filled with insulating resin 80, in the printed circuit board 50 that has undergone the fourteenth step.

In this embodiment, liquid pre-hardened insulating resin 80 is applied in the cavities by dispensing, followed by hardening the resin 80, so that the cavities are filled with the resin 80.

The first to fifteen steps provide an electronic-component carrier board 100 that carries the two semiconductor devices 60 and 70 in the cavities of the printed circuit board 50, which are electrically connected to the board 50 by flip chip mounting.

As disclosed above, several bumps can be simultaneously formed in the cavities of the printed circuit board, according to the printed circuit board, the production method therefor, the electronic-component carrier board using the printed circuit board, and the production method therefor, of the present invention.

Therefore, the present invention achieves flip chip mounting of electronic components, such as semiconductor devices, on a printed circuit board, at higher productivity, with no requirements of highly multi-layered and bulk structures to the printed circuit board and also the electronic-component carrier board using such a printed circuit board.

Moreover, the present invention requires no particular underfill in flip chip mounting because the bumps of the printed circuit board are isolated from one another by the insulation layers.

[Modification]

Disclosed next with reference to FIG. 16 is a modification to the embodiments described above. In FIG. 16, the components the same as or analogous to those in FIGS. 1 to 15 are given the same reference numerals.

Performed first are the processes that correspond to the first to twelfth steps described above to prepare the double-sided wiring board 20 shown in FIG. 12.

The process corresponding to the thirteenth step described above is applied to the double-sided wiring board 20 after the sixth conductive layer 36 is covered with a resist pattern for use in plating (not shown), to form gold-plated layers 48 on the exposed surfaces of the first and second conductors 17 and 27, thus having the printed circuit board 50, as shown in FIG. 13.

The first and second conductors 17 and 27 covered with the gold-plated layers 48 are used as first and second bumps 51 and 52 for use in electrical connections between the electronic components (the semiconductors 60 and 70) and the printed circuit board 50, in the same manner as the embodiments disclosed above.

The processes corresponding to the fourteenth and fifteenth steps described above are applied to the double-sided wiring board 50 that has undergone the processes described above.

A seventh insulation layer 91 is then formed over the fourth insulation layer 35 and the insulating resin 80 to cover the sixth wiring layer 36, and then a ninth wiring layer 93 is formed on the insulation layer 91, by a known process.

In the same way, an eighth insulation layer 92 is formed over the sixth insulation layer 40 (the lower side in FIG. 16) to cover the eighth wiring layer 41, and then a tenth wiring layer 94 is formed on the eighth insulation layer 92 (the lower side in FIG. 16), by a known process.

Gold-plated layers 96 are then formed on the ninth wiring layer 93 and also the tenth wiring layer 94, to have an electronic-component carrier board 110, as shown in FIG. 16, according to the modification.

The electronic-component carrier board 110 and the production method therefor can provide wiring patterns also over the cavity that houses the semiconductors 60 and 70, different from the electronic-component carrier board 100 shown in FIG. 15.

It is further understood by those skilled in the art that the foregoing description is a preferred embodiment of and a modification to each of the printed circuit board, the production method therefor, the electronic-component carrier board using the printed circuit board, and the production method therefor, and that various changes and modifications may be made in the invention without departing from the sprit and scope thereof.

For example, in the embodiments and modification, the cavity is filled with the insulation resin 80 after the two semiconductors 60 and 70 are housed in the cavity by flip chip mounting. These processes may, however, be changed in such a way that the second counterbore 46 is filled with insulating resin after the semiconductor 60 is housed in the cavity by flip chip mounting and then the first counterbore 45 is filled with insulating resin after the semiconductor 70 is housed in the cavity by flip chip mounting. The insulating resin to be used in filling the first and second counterbores 45 and 46 may be the same or different from each other in composition and/or viscosity.

As disclosed in detail, the printed circuit board, the production method therefor, the electronic-component carrier board using the printed circuit board, and the production method therefor, of the present invention, allow flip chip mounting to be used in mounting electronic components, such as semiconductor devices, on the printed circuit board at higher productivity, without a further multi-layered and a larger structure for the printed circuit board, or the electronic-component carrier board using such a printed circuit board.

What is claimed is:

1. A printed wiring board comprising:
a substrate having a first surface and a second surface on both sides of the substrate;
a cavity provided on the first surface that caves in towards the second surface;
a plurality of bumps formed in the cavity that protrude towards the first surface;
an insulation layer filled in the cavity, the bumps being isolated from one another by the insulation layer, a top of each bump that protrudes towards the first surface and a zone in the cavity and close to the top being exposed in the cavity without being covered by the insulation layer.

2. A method of producing a printed wiring board comprising the steps of:
forming a plurality of bumps on a substrate surface;
forming an insulation layer having a sheet-like reinforcement material and insulating resin on the substrate surface to cover the bumps with the reinforcement material via the insulating resin;
removing the reinforcement material from a zone on the substrate surface having the bumps formed in the zone so that the insulating material on the bumps remains; and
emitting a laser beam to the insulating material that remains on the bumps to remove the insulating material so that the bumps are exposed on the substrate surface.

3. An electronic-component carrier board comprising:
a substrate having a first surface and a second surface on both sides of the substrate;
a cavity provided on the first surface that caves in towards the second surface;
a plurality of bumps formed in the cavity that protrude towards the first surface;
an insulation layer filled in the cavity, the bumps being isolated from one another by the insulation layer, a top of each bump that protrudes towards the first surface and a zone in the cavity and close to the top being exposed in the cavity without being covered by the insulation layer; and
at least one electronic component housed in the cavity and having a plurality of electrodes that are electrically connected to the bumps.

4. A method of producing an electronic-component carrier board comprising the steps of:
forming a plurality of bumps on a substrate surface;
forming an insulation layer having a sheet-like reinforcement material and insulating resin on the substrate surface to cover the bumps with the reinforcement material via the insulating resin;
removing the reinforcement material from a zone on the substrate surface having the bumps formed in the zone so that the insulating material on the bumps remains;
emitting a laser beam to the insulating material that remains on the bumps to remove the insulating material so that the bumps are exposed on the substrate surface;
housing at least one electronic component having a plurality of electrodes in the cavity; and
electrically connecting the electrodes to the bumps.
